(19) United States
(12) Patent Application Publication
(10) Pub. No.: US 2013/0139878 A1
(43) Pub. Date: Jun. 6, 2013

(54) USE OF A1 BARRIER LAYER TO PRODUCE HIGH HAZE ZNO FILMS ON GLASS SUBSTRATES

(71) Applicants: Yashraj K. Bhatnagar, Santa Clara, CA (US); Brenden McComb, Mountain View, CA (US); Xiao Ming, Xi'an (CN); Deepak Jadhav, Hubil (IN); Anantha K. Subramani, San Jose, CA (US); Wei D. Wang, San Jose, CA (US); Jianshe Tang, San Jose, CA (US)

(72) Inventors: Yashraj K. Bhatnagar, Santa Clara, CA (US); Brenden McComb, Mountain View, CA (US); Xiao Ming, Xi'an (CN); Deepak Jadhav, Hubil (IN); Anantha K. Subramani, San Jose, CA (US); Wei D. Wang, San Jose, CA (US); Jianshe Tang, San Jose, CA (US)

(73) Assignee: APPLIED MATERIALS, INC., Santa Clara, CA (US)

(21) Appl. No.: 13/266,738

(22) PCT Filed: Apr. 7, 2011
(86) PCT No.: PCT/US11/31633

§ 371 Date: Mar. 22, 2012

Related U.S. Application Data
(60) Provisional application No. 61/321,808, filed on Apr. 7, 2010.

(51) Int. Cl. H01L 31/18; H01L 31/0224; H01L 31/04

(52) U.S. Cl. CPC H01L 31/1884; H01L 31/04; H01L 31/022483; H01L 31/1864
USPC 136/256; 427/74

(57) ABSTRACT

Embodiments of the invention provide a method for forming a solar cell including forming a layer comprising alumina on a substrate and forming a transparent conductive layer on the layer comprising alumina. The method may also include forming a transparent conductive seed layer on the layer comprising alumina and forming a transparent conductive bulk layer on the transparent conductive seed layer. Embodiments of the invention also include photovoltaic devices having a substrate, a layer comprising alumina adjacent to the substrate, a zinc oxide-containing transparent conductive seed layer adjacent to the layer comprising alumina, and a zinc oxide-containing transparent conductive bulk layer adjacent the zinc oxide-containing transparent conductive seed layer.

### BACKGROUND OF THE INVENTION

1. Field of the Invention

Embodiments of the present invention generally relate to solar cells and methods for forming the same. More particularly, embodiments of the present invention relate to methods for manufacturing thin-film solar cells on glass substrates.

2. Description of the Related Art

Photovoltaic (PV) devices or solar cells are devices which convert sunlight into direct current (DC) electrical power. Typical thin film type PV devices, or thin film solar cells, have one or more p-i-n junctions. Each p-i-n junction comprises a p-type layer, an intrinsic type layer, and an n-type layer. When the p-i-n junction of the solar cell is exposed to light (consisting of energy from photons), a photon of light energy is converted into electrical energy through the PV effect.

Typically, a thin film solar cell includes active regions, or photoelectric conversion units, and a transparent conductive oxide (TCO) film disposed as a front electrode and/or as a backside electrode to enable light to penetrate the film and enter the photoelectric conversion active regions of the cell. The photoelectric conversion unit includes a p-type silicon layer, an n-type silicon layer, and an intrinsic type (i-type) silicon layer sandwiched between the p-type and n-type silicon layers. Several types of silicon films including microcrystalline silicon film (pc-Si), amorphous silicon film (a-Si), polycrystalline silicon film (poly-Si), and the like may be utilized to form the p-type, n-type, and/or i-type layers of the photoelectric conversion unit. The backside electrode may contain one or more conductive layers.

TCO layers are formed to have particular optical and conductive properties. For example, some TCO layers are processed to increase the scattering of light passing through the TCO layers and into the photoelectric conversion. Specific types of glass substrates, such as borosilicate glass, may be necessary to form TCO layers that will have the desired surface texture to increase light scattering, and thus improve solar cell efficiency. However, those special glass substrates are more expensive, increasing manufacturing costs for large scale solar cell production. One way to reduce manufacturing costs is to use a commercially available, and thus likely less expensive, glass substrate such as low iron float glass or soda lime glass, compared to specialty glass, such as borosilicate glass. However, achieving the desired surface morphology of TCO layers using these glass substrates has proved elusive, if not impossible, on a large scale production. Additionally, the less expensive glass substrates may have contaminants that can poison the photoelectric conversion unit and other layers.

There is a need for improving the light scattering properties of solar cell devices and reducing manufacturing costs. Therefore, there is a need for an improved process of forming a solar cell that has TCO surface morphology to provide a desired amount of light scattering, strong layer adhesion/bonding, and high overall performance.

### SUMMARY OF THE INVENTION

Embodiments of the invention generally provide a method for forming a solar cell and solar cell devices. The method includes forming a layer comprising alumina on a substrate and forming a transparent conductive layer on the layer comprising alumina. The method may also include forming a zinc based seed layer on the layer comprising alumina and forming a transparent conductive bulk layer on the zinc based transparent conductive seed layer.

In one embodiment, a method of forming a solar cell includes forming a nucleation promotion layer comprising alumina on a substrate, forming a barrier layer on the nucleation promotion layer, forming a zinc oxide-containing transparent conductive seed layer on the barrier layer, and forming a zinc oxide-containing transparent conductive bulk layer on the zinc oxide-containing transparent conductive seed layer.

In one embodiment, a photovoltaic device includes a substrate, a layer comprising alumina adjacent to the substrate, a zinc oxide-containing transparent conductive seed layer adjacent the layer comprising alumina, and a zinc oxide-containing transparent conductive bulk layer adjacent to the zinc oxide-containing transparent conductive seed layer.

### BRIEF DESCRIPTION OF THE DRAWINGS

So that the manner in which the above-recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments. The patent or application file contains at least one drawing executed in color. Copies of this patent or patent application publication with color drawing(s) will be provided by the Office upon request and payment of the necessary fee.

FIG. 1 depicts a schematic cross-sectional view of one embodiment of a process chamber in accordance with the invention.

FIG. 2A depicts an exemplary cross-sectional view of a thin film PV solar cell in accordance with one embodiment of the present invention.

FIG. 2B depicts an exemplary cross-sectional view of a thin film PV solar cell in accordance with one embodiment of the present invention.

FIG. 2C depicts an exemplary cross-sectional view of a thin film PV solar cell in accordance with one embodiment of the present invention.

FIG. 3 is depicts a process flow diagram of manufacturing a nucleation promotion layer and a TCO layer according to one embodiment of the invention.

FIG. 4 is a micrograph of an etched ZnO:Al film on a borosilicate glass substrate.

FIG. 5 is a micrograph of an etched ZnO:Al film on a soda lime glass substrate.

FIG. 6 is a micrograph of an etched ZnO:Al film on a soda lime glass with a nucleation promotion layer.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments of the invention provide thin-film photovoltaic devices and the methods of forming such devices. In particular, embodiments of the invention provide methods for forming a nucleation promotion layer (NPL) that promotes a particular texture or surface morphology of a later formed transparent conductive layer on the nucleation promotion layer and a barrier layer during formation of photovoltaic devices.

Transparent conductive layers include transparent conductive oxides (TCO), such as aluminum doped zinc oxide (AZO) or ZnO:Al. Transparent conductive layers are transparent and electrically conductive, thereby enabling transparent conductive layers, such as TCO, to be formed as front contact structures in thin film solar devices, where the front side is generally the side of the solar cell device through which light enters for the photovoltaic generation of electricity. Transparent conductive layers may need to have a surface texture which yields very high haze or light scattering properties to improve device efficiencies. Haze is a measure of how much light is defracted or scattered when the light passes through a film. A collimated light is shone through a sample, and the light in the collimated direction and off the collimated direction is measured. The larger amount of light off the collimated direction, the larger the haze. Increased light scattering increases the length of the path light travels in the solar cell and reduces reflection. As a result, more light will be absorbed by the photoabsorbing portions or photojunction layers of a photovoltaic device, thereby improving light to electricity conversion efficiency. A TCO layer with suitable surface texture will scatter light very efficiently in order to extend the effective path length of light within the active silicon layers.

One conventional method of improving or enhancing light scattering relies on post-deposition wet-chemical etching of initially smooth sputter-deposited TCO films. The sputtered TCO films become rough by wet-chemical etching, which roughness thereby introduces light scattering and subsequent light trapping in thin film solar cells. The surface topography determines the light-trapping and light-scattering capability to a large extent. The wet etch process, however, may not improve the surface texture of transparent conductive layers formed on certain types of substrates, particularly low-end commercial grade glass substrates. For example, to obtain the necessary surface roughness to scatter light, special types of glass substrates may be necessary, such as borosilicate glass, and are specially prepared and processed prior to TCO deposition on the glass substrate. It has been found that TCO films formed on borosilicate glass tends to form desirable texture and roughness for light scattering. The TCO layer deposited on the glass is subsequently wet etched to achieve a desired texture that will enhance and enable light scattering.

However, deposition of an AZO layer on a soda lime glass or low iron glass having the necessary light scattering properties has proved very difficult, if not impossible to achieve. It should be noted that soda lime glass with iron removed is low iron glass. Additionally, low iron glass has a reduced ferric oxide content which produces better transmission of light through the glass. Furthermore, borosilicate glass is more expensive than commercially available lower grade glass, such as low iron float glass or soda lime glass. In glass making, glass usually begins as low iron float glass or soda lime glass, which is considered low grade glass, and then other processes may be performed and compounds added to improve the glass's grade.

Transparent conductive layers may need certain types of crystal structures to achieve a surface morphology with very high haze or light scattering properties instead of relying on conventional wet-etch techniques. Embodiments of the invention enable processing of lower grade glass substrates while enabling formation of transparent conductive layers having desirable surface morphology and optical characteristics, which may improve photovoltaic device efficiencies by as much as 8-10%.

In one embodiment, a layer comprising alumina, which serves as a nucleation promotion layer (NPL), and a barrier layer may be formed on the glass substrate by a sputter deposition process. The type of layers deposited on the glass substrate will depend on the sputter target material and process gases used. It should be noted that alumina as used herein refers aluminum oxide, typically having the chemical formula Al₂O₃ but also including non-stoichiometric aluminum oxide AlₓO_{y}. A TCO layer may then be sputter deposited by supplying process gas mixtures and target materials, each of which may be different gas mixtures and target materials than those used for forming the layer comprising alumina and the barrier layer. In some embodiments, the target material for the TCO layer deposition process is selected to deposit a TCO layer having a desired dopant concentration formed therein. Composition of the TCO layer at its interface with another layer or surface of a substrate can influence the absorption and reflection of light at the interface, which affects the efficiency of the solar cell.

Embodiments of the invention may be practiced in a physical vapor deposition (PVD) chamber or system or plasma-enhanced chemical vapor deposition (CVD) chambers or systems. Examples of various process chambers that may be adapted to benefit from the invention are a PVD or CVD process chamber, available from Applied Materials, Inc., Santa Clara, Calif. It is contemplated that other sputter process chambers or chemical vapor deposition chambers, including those from other manufactures, may be adapted to practice the present invention.

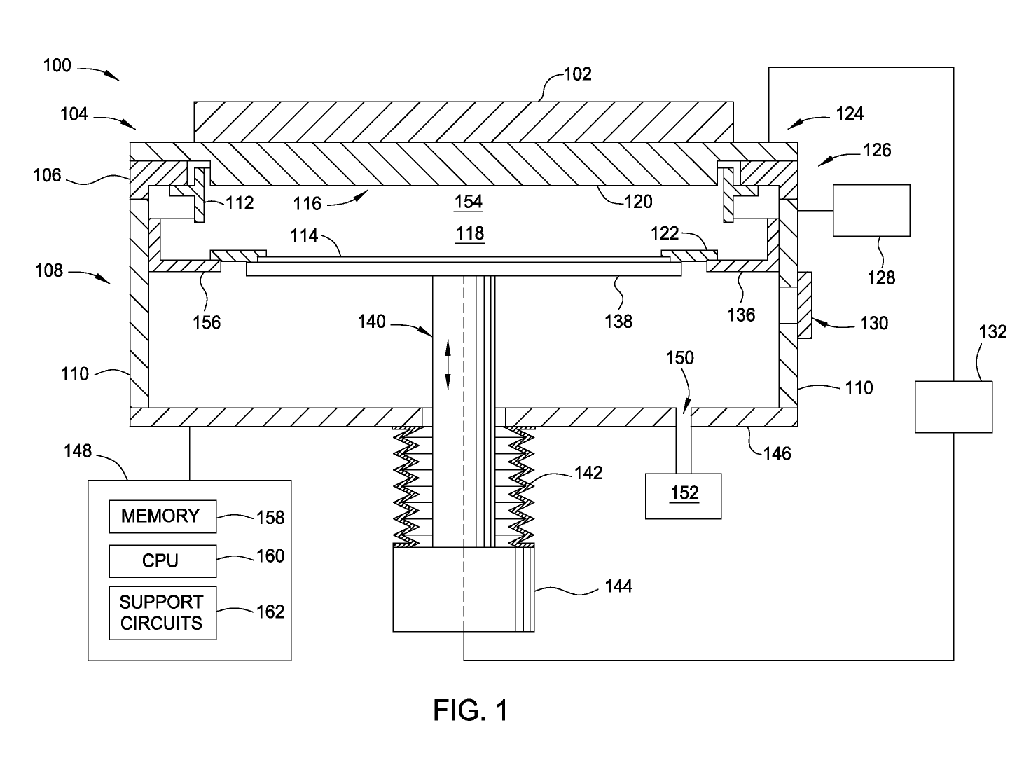

FIG. 1 schematically illustrates a sputter process chamber 100 suitable for sputter depositing materials according to one embodiment of the invention. While the discussion and related figures shown herein illustrate a planar magnetron type process chamber 100, this configuration is not intended to be limiting as to the scope of the invention described herein, since cylindrical and other shaped targets may also be used.

The process chamber 100 includes a chamber body 108 having a processing volume 118 defined therein. The chamber body 108 has sidewalls 110 and a bottom 146. The dimensions of the chamber body 108 and related components of the process chamber 100 are not limited and generally are proportionally larger than the size of the substrate 114 to be processed. Any substrate size may be processed in a suitably configured chamber. Examples of suitable substrate sizes include substrate having a surface area of about 2,000 centimeter square or more, such as about 4,000 centimeter square or more, for example about 10,000 centimeter square or more. In one embodiment, a substrate having a surface area of about 50,000 centimeter square or more or more may be processed.

A chamber lid assembly 104 is mounted on the top of the chamber body 108. The chamber body 108 may be fabricated from aluminum or other suitable materials. A substrate access port 130 is formed through the sidewall 110 of the chamber body 108, facilitating the transfer of a substrate 114 (i.e., a solar panel, a flat panel display substrate, a semiconductor wafer, or other workpiece) into and out of the process chamber 100. The access port 130 may be coupled to a transfer chamber and/or other chambers of a substrate processing system.

A gas source 128 is coupled to the chamber body 108 to supply process gases into the processing volume 118. In one embodiment, process gases may include inert gases, non-reactive gases, and reactive gases. Examples of process gases that may be provided by the gas source 128 include, but not limited to, argon gas (Ar), helium (He), nitrogen gas (N₂), oxygen gas (O₂), H₂, NO₂, N₂O, and H₂O, among others.

A pumping port 150 is formed through the bottom 146 of the chamber body 108. A pumping device 152 is coupled to the processing volume 118 to evacuate and control the pressure therein. In one embodiment, the pressure level of the process chamber 100 may be maintained at about 1 Torr or less. In another embodiment, the pressure level of the process chamber 100 may be maintained at about 10⁻³ Torr or less. In yet another embodiment, the pressure level of the process chamber 100 may be maintained at about 10⁻⁵ Torr to about 10⁻⁷ Torr. In another embodiment, the pressure level of the process chamber 100 may be maintained at about 10⁻⁷ Torr or less.

The lid assembly 104 generally includes a target 120 and a ground shield assembly 126 coupled thereto. The target 120 provides a material source that can be sputtered and deposited onto the surface of the substrate 114 during a PVD process. The target 120, or target plate, is fabricated from a component of the PVD deposited film layer. A high voltage power supply, such as a power source 132, is connected to the target 120 to facilitate the sputtering of material from the target 120. The power supply may be a DC power source, an RF power source, or other type of power source depending on the type of target material and processing conditions.

In one embodiment when depositing a layer comprising alumina, the target 120 may be fabricated from aluminum or an aluminum alloy. In another embodiment, the target 120 may be fabricated from an aluminum oxide material. In one embodiment when depositing a transparent conductive layer, the target 120 may be fabricated from a material containing zinc (Zn) metal. In another embodiment, the target 120 may be fabricated from materials including metallic zinc (Zn), zinc alloy, zinc and aluminum alloy and the like. In yet another embodiment, the target 120 may be fabricated from materials including zinc containing materials and aluminum containing materials. In one embodiment, the target may be fabricated from a zinc oxide and an aluminum oxide material.

In one embodiment, the target 120 is fabricated from a zinc and aluminum alloy having a desired ratio of zinc element to aluminum element fabricated in the target 120. The aluminum elements formed in the target 120 assists maintaining the target conductivity at a certain range so as to efficiently enable a uniform sputtering process across the target surface. The aluminum elements in the target 120 are also believed to increase the transmittance of the deposited layer. In the embodiment wherein the target 120 is fabricated from ZnO and Al₂O₃ alloy, the Al₂O₃ dopant concentration in the ZnO target is less than about 5 percent by weight, for example 3 percent by weight. In another embodiment, the Al₂O₃ dopant concentration in the ZnO target is less than about 2 percent by weight, such as less than about 0.5 percent by weight, for example, about 0.25 percent by weight.

The target 120 generally includes a peripheral portion 124 and a central portion 116. The peripheral portion 124 is disposed over the sidewalls 110 of the chamber 100. The central portion 116 of the target 120 may have a curvature surface slightly extending towards the surface of the substrate 114 disposed on a substrate support 138. The spacing between the target 120 and the substrate support 138 is maintained between about 50 mm and about 150 mm during processing. It is noted that the dimension, shape, materials, configuration and diameter of the target 120 may be varied for specific process or substrate requirements. In one embodiment, the target 120 may further include a backing plate having a central portion bonded and/or fabricated from a material desired to be sputtered onto the substrate surface. The target 120 may also include adjacent tiles or material segments that together form the target.

Optionally, the lid assembly 104 may further comprise a magnetron assembly 102 mounted above the target 120 which enhances efficient sputtering materials from the target 120 during processing. Examples of the magnetron assembly 102 include a linear magnetron, a serpentine magnetron, a spiral magnetron, a double-digitated magnetron, a rectangularized spiral magnetron, among others.

The ground shield assembly 126 of the lid assembly 104 includes a ground frame 106 and a ground shield 112. The ground shield assembly 126 may also include other chamber shield member, target shield member, dark space shield, dark space shield frame. The ground shield 112 is coupled to the peripheral portion 124 by the ground frame 106 defining an upper processing region 154 below the central portion of the target 120 in the processing volume 118. The ground frame 106 electrically insulates the ground shield 112 from the target 120 while providing a ground path to the chamber body 108 of the process chamber 100 through the sidewalls 110. The ground shield 112 constrains plasma generated during processing within the upper processing region 154 and dislodges target source material from the confined central portion 116 of the target 120, thereby allowing the dislodged target source to be mainly deposited on the substrate surface rather than chamber sidewalls 110. In one embodiment, the ground shield 112 may be formed by one or more work-piece fragments and/or a number of these pieces bonding by a substrate process, such as welding, gluing, high pressure compression, etc.

A shaft 140 extending through the bottom 146 of the chamber body 108 couples to a lift mechanism 144. The lift mechanism 144 is configured to move the substrate support 138 between a lower transfer position and an upper processing position. A bellows 142 circumscribes the shaft 140 and coupled to the substrate support 138 to provide a flexible seal therebetween, thereby maintaining vacuum integrity of the chamber processing volume 118.

A shadow frame 122 is disposed on the periphery region of the substrate support 138 and is configured to confine deposition of source material sputtered from the target 120 to a desired portion of the substrate surface. A chamber shield 136 may be disposed on the inner wall of the chamber body 108 and have a lip 156 extending inward to the processing volume 118 configured to support the shadow frame 122 disposed around the substrate support 138. As the substrate support 138 is raised to the upper position for processing, an outer edge of the substrate 114 disposed on the substrate support 138 is engaged by the shadow frame 122 and the shadow frame 122 is lifted up and spaced away from the chamber shield 136. When the substrate support 138 is lowered to the transfer position adjacent to the substrate access port 130, the shadow frame 122 is set back on the chamber shield 136. Lift pins (not shown) are selectively moved through the substrate support 138 to lift the substrate 114 above the substrate support 138 to facilitate access to the substrate 114 by a transfer robot or other suitable transfer mechanism.

A controller 148 is coupled to the process chamber 100. The controller 148 includes a central processing unit (CPU) 160, a memory 158, and support circuits 162. The controller 148 is utilized to control the process sequence, regulating the gas flows from the gas source 128 into the chamber 100 and controlling ion bombardment of the target 120. The CPU 160 may be of any form of a general purpose computer processor that can be used in an industrial setting. The software routines can be stored in the memory 158, such as random access memory, read only memory, floppy or hard disk drive, or other form of digital storage. The support circuits 162 are conventionally coupled to the CPU 160 and may comprise cache, clock circuits, input/output subsystems, power supplies, and the like. The software routines, when executed by the CPU 160, transform the CPU into a specific purpose computer (controller) 148 that controls the process chamber 100 such that the processes are performed in accordance with the present invention. The software routines may also be stored and/or executed by a second controller (not shown) that is located remotely from the chamber 100.

During processing, the material is sputtered from the target 120 and deposited on the surface of the substrate 114. The target 120 and the substrate support 138 are biased relative to each other by the power source 132 to maintain a plasma formed from the process gases supplied by the gas source 128. The ions from the plasma are accelerated toward and strike the target 120, causing target material to be dislodged from the target 120. The dislodged target material and process gases form a layer or layers on the substrate 114 with desired compositions, as will be subsequently described in more detail.

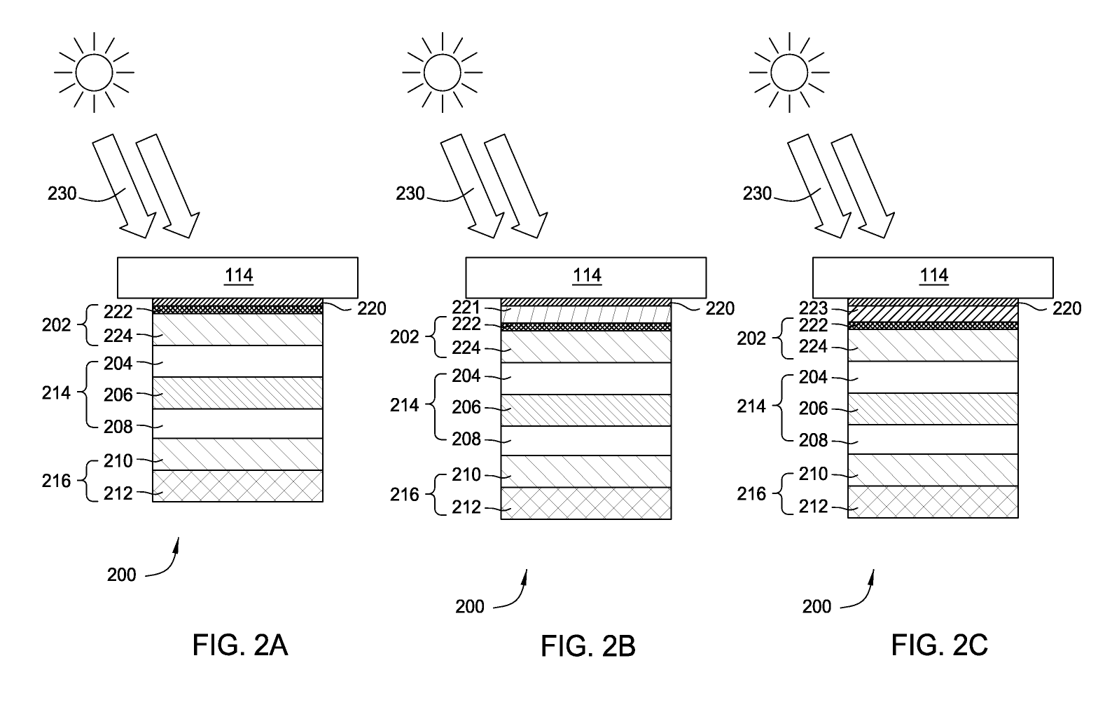

FIGS. 2A-2C depict exemplary cross sectional views of thin film PV solar cells 200 in accordance with various embodiments of the present invention. In one embodiment, the thin film PV solar cell 200 is an amorphous silicon-based solar cell device that is formed on a substrate, such as the substrate 114 that is processed in the process chamber 100 of FIG. 1. The substrate 114 may be a thin sheet of borosilicate glass, alumino-borosilicate glass, soda lime glass, low iron float glass, or other suitable material. The substrate 114 may have a surface area greater than about 1 square meter, such as greater than about 2 square meters. Alternatively, the thin film PV solar cell 200 may also be fabricated as crystalline, microcrystalline, amorphous, or other type of silicon-based thin films as needed.

A layer comprising alumina 220, which functions at least as an NPL, may be formed adjacent to the substrate 114, and a TCO layer 202 may be disposed adjacent the NPL layer comprising alumina 220. An NPL layer aids in the nucleation of a later formed transparent conductive layer, such as TCO layer 202. To improve surface texture and roughness of the TCO layer, the NPL layer helps promote the nucleation of the TCO layer to form specific crystal grain orientations, while using lower grade glass substrates, that will yield a particular surface morphology of the TCO layer with textures and roughness that improve the light scattering capabilities of the TCO layer 202, such as a zinc oxide-containing transparent conductive layer. Other types of transparent conductive layers that may be used include boron or gallium doped zinc-oxide layers.

A photoelectric unit 214 is formed on a transparent conductive layer, such as a TCO layer 202, disposed on the NPL layer comprising alumina 220. The photoelectric unit 214, which may be a photoelectric conversion unit or a photoelectric layer, includes a p-type semiconductor layer 204, an n-type semiconductor layer 208, and an intrinsic type (i-type) semiconductor layer 206 sandwiched therebetween as a photoelectric conversion layer.

The p-type and n-type semiconductor layers 204, 208 may be silicon based materials doped by an element selected either from group III or V. A group III element doped silicon film is referred to as a p-type silicon film, while a group V element doped silicon film is referred to as a n-type silicon film. In one embodiment, the p-type semiconductor layer 204 may be a boron doped silicon film and the n-type semiconductor layer 208 may be a phosphorus doped silicon film. The doped silicon films 204, 208 may be an amorphous silicon film (a-Si), a polycrystalline film (poly-Si), and a microcrystalline film (pc-Si) with a total thickness between about 5 nm and about 50 nm. Alternatively, the doped element in semiconductor layers 204, 208 may be selected to meet device requirements of the PV solar cell 200. The p-type and n-type semiconductor layers 204, 208 may be deposited by a CVD process or other suitable deposition process.

The i-type semiconductor layer 206 is a non-doped type silicon based film. The i-type semiconductor layer 206 may be deposited under controlled process conditions to provide film properties having improved photoelectric conversion efficiency. In one embodiment, the i-type semiconductor layer 206 may be fabricated from i-type polycrystalline silicon (poly-Si), microcrystalline silicon (pc-Si), amorphous silicon (a-Si), or hydrogenated amorphous silicon (a-Si:H).

After the photoelectric unit 214 is formed on the TCO layer 202, a back reflector 216 is formed on the photoelectric unit 214. In one embodiment, the back reflector 216 may be formed by a stacked film that includes a transparent conductive layer, such as a transparent conductive oxide (TCO) layer 210, and a conductive layer 212. The conductive layer 212 may be at least one of Ti, Cr, Al, Ag, Au, Cu, Pt, or their alloys.

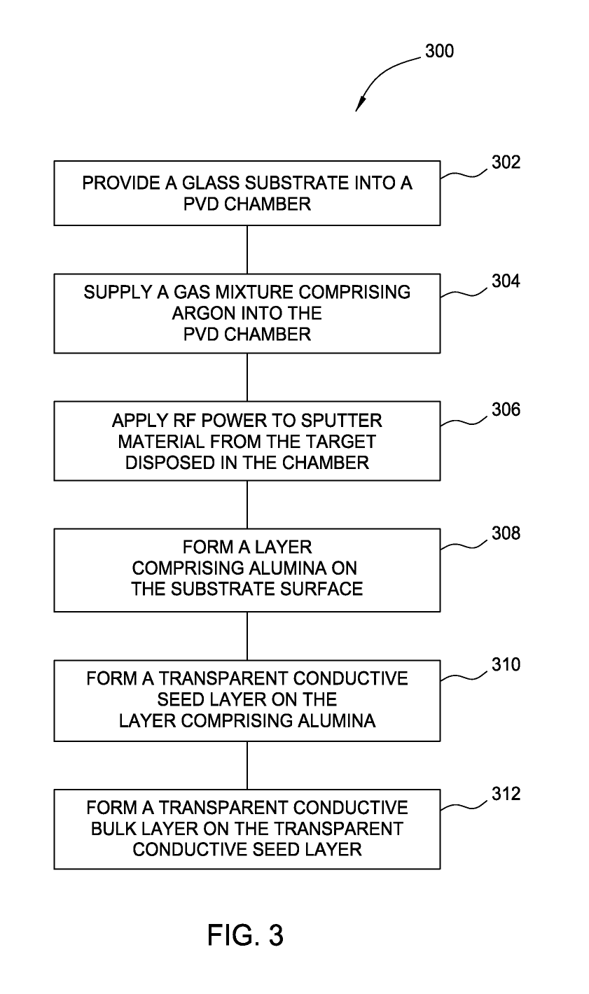

The transparent conductive oxide (TCO) layer 210 may be fabricated from a material similar to the TCO layer 202 formed on the substrate 114. For example, in one embodiment, the transparent conductive oxide (TCO) layers 202, 210 may be fabricated from a ZnO layer having a desired Al dopant concentration. Embodiments of a process 300 for forming a ZnO:Al layer are described below with reference to FIG. 3. The transparent conductive oxide (TCO) layer 210 may alternatively be fabricated from a group consisting of tin oxide (SnO₂), indium tin oxide (ITO), zinc oxide (ZnO), or combinations thereof.

In embodiments depicted in FIG. 2A-2C, at least one of the transparent conductive oxide (TCO) layers 202, 210 is fabricated by sputter deposition processes of the present invention. The sputter deposition processes of TCO layers 202, 210 may be performed in the processing chamber 100, as described in FIG. 1. The TCO layer 202 comprises a seed layer 222 and a bulk layer 224, formation of which will be further described with respect to FIG. 3. In one embodiment, the seed layer 222 is a zinc oxide-containing transparent conductive seed layer and the bulk layer 224 is a zinc oxide-containing transparent conductive bulk layer.

In operation, the incident light 230 provided by the environment is supplied to the PV solar cell 200. The photoelectric unit 214 in the PV solar cell 200 absorbs the light energy and converts the light energy into electrical energy by operation of the p-i-n junctions formed in the photoelectric unit 214, thereby generating electricity or energy. Alternatively, the PV solar cell 200 may be fabricated or deposited in a reversed order. For example, the substrate 114 may be disposed over the back reflector 216.

In one embodiment of the thin film PV solar cell 200, a layer comprising alumina 220, which functions as a nucleation promotion layer, is formed between the glass substrate and the TCO layer 202. The layer comprising alumina 220 may be a thin layer 20 Å to 30 Å thick having a refractive index between 1.6 and 1.7 that provides a smooth transition between the refractive indices of the glass substrate 114 and the TCO layer 202. The refractive index of alumina is closer to glass than AZO, one type of TCO layer 202. Thus, the layer comprising alumina 220 provides less reflective light loss for the PV solar cells 200.

In some embodiments, the layer comprising alumina 220 may be amorphous. The glass substrate may also have an amorphous structure which may enable a strong bonding structure between the glass substrate and the layer comprising alumina. Additionally, the layer comprising alumina 220 may be discontinuous and form a porous pattern, i.e. because the formed layer comprising alumina may be thin, “islands” of the layer comprising alumina 220 may be formed, exposing portions of the substrate. The “islands” may still be connected together in between the exposed portions of the substrate thus forming a porous pattern. The glass substrate may have physical defects and/or holes that the layer comprising alumina 220 covers and/or fills up, yielding a smoother surface for later transparent conductive layer formation and deposition. Additionally, it is believed that the amorphous nature and the porous pattern of the layer comprising alumina 220 provide nucleation sites for a transparent conductive layer to grow. Thus, the layer comprising alumina 220 may yield a better bonding structure between the glass substrate 114 and the TCO layer 202. The layer comprising alumina may be a matrix of various aluminum based materials, such as metallic aluminum, partially converted aluminum to alumina i.e. alumina in different states including non-stoichiometric alumina. For example, the matrix may include aluminum and alumina, aluminum with nano particles of alumina, aluminum nano particles in alumina and/or combinations thereof.

The formation of the layer comprising alumina 220 on the glass substrate 220 may be accomplished using various techniques, such as PVD or CVD deposition, and methods. Formation of the layer comprising alumina 220 using a PVD technique will now be described. The glass substrate 114 is preferably cleaned and particles removed prior to placing the glass substrate 114 in a PVD chamber, such as PVD chamber 100 shown in FIG. 1. In one embodiment, an aluminum layer is deposited on the glass substrate 114. A sputtering gas, such as argon, enters the PVD chamber 100 and will sputter the target 120, such as an aluminum target, causing aluminum to deposit on the glass substrate 114. In another embodiment, the sputtering gas may include O₂ mixed with Ar, but the O₂ may comprise a small percentage of the gas mixture, such as less than 10% or less than 5% O₂. The spacing between the glass substrate 114 and the target 120 is about 19 cm.

During the aluminum deposition and subsequent annealing processes, it is believed that the aluminum pulls oxygen from the oxygen rich glass (the surface of the glass may be about 67% oxygen), thus forming an oxide film, e.g., aluminum oxide (Al₂O₃) or alumina, on the glass surface. The alumina formation process may begin during the aluminum sputtering process as the deposited aluminum reacts with oxygen on the glass surface, and completed during a subsequent annealing process. The glass substrate may also have some water on the surface, and because of the water and oxygen on the glass surface, although aluminum may be sputtered from a target in the PVD chamber, a matrix of aluminum and alumina may be formed on the glass substrate. It should be noted that the aluminum oxide that forms on the glass substrate surface may not be a true stoichiometric oxide, but may be some form of aluminum oxide.

The temperature of the PVD process may be between about 200° C. and about 500° C. such as about 400° C. In one embodiment, the temperature is about 250° C. The low temperature deposition of the layer comprising alumina yields an amorphous structure. The amorphous nature of the alumina may also make it a barrier layer, which will be discussed in greater detail below with reference to FIGS. 2B-2C.

After sputtering the aluminum onto the glass substrate, the glass substrate is removed from the PVD chamber to an annealing chamber where the deposited layer, which may comprise alumina, is annealed and degassed in an argon atmosphere for about 5 minutes at a temperature of about 450° C. In one embodiment, the annealing temperature may be from about 300° C. to about 500° C., and lasts from about 1 minute to about 30 minutes, for example about 5 minutes. In another embodiment, the annealing atmosphere may include a non-reactive gas, such as nitrogen (N₂), or a mixture of reactive and non-reactive gases, such as N₂ and O₂. In the N₂ and O₂ mixture, the O₂ may comprise less than 5% of the annealing atmosphere.

Water and carbon dioxide may be trapped between the layers of glass and aluminum/alumina matrix, and degassing helps to remove those contaminants that can affect the properties of the later deposited TCO layer. Annealing of the layer comprising alumina may take place in an inert atmosphere, a reactive atmosphere, in an oxygen atmosphere, or a forming gas (N₂/H₂). The annealing may also help increase the density of the amorphous film. When using PVD deposition, the substrate may be cold, resulting in film sticking to single locations on the substrate. Annealing helps realign the film to increase the density. This may be particularly useful in forming a barrier layer of alumina as will be discussed below.

After the annealing has taken place, the glass substrate may be placed back into the PVD chamber and the TCO layer 202 may then be deposited on the NPL layer 220. In one embodiment, the annealing chamber is connected with the PVD chamber 100 so that the substrate 114 passes between the two chambers in a vacuum environment. In other embodiments, the glass substrate 114 may be removed from the PVD chamber 100 to transfer the substrate 114 to an anneal chamber not connected to the PVD chamber. In other words, in some cases the layer comprising alumina 220 may be exposed to the ambient atmosphere as the substrate is transferred between chambers for subsequent processing.

In some embodiments, instead of depositing an aluminum layer on the glass substrate to form an alumina layer as the aluminum reacts with oxygen during the sputtering process and/or the annealing process, alumina may be directly deposited on the glass substrate. In one embodiment, Alumina is deposited on a glass substrate using a PVD technique. In an embodiment where the target material is 100% alumina, the target will be powered by an RF source and sputtered with argon.

Various advantages may result when forming a layer comprising alumina before depositing the TCO layer 202. The layer comprising alumina, an oxide film, forms a better bond with the TCO layer 202 than a direct bond between the TCO layer 202 and the glass substrate 114. Furthermore, the annealing process forms strong bonds between the layer comprising alumina and the glass substrate. The annealing vaporizes any liquid on the layer comprising alumina and any exposed surfaces of the substrate, which liquid may prevent any adhesion of subsequent layers on the glass and the layer comprising alumina. Additionally, it is believed that the high oxygen content surface of the layer comprising alumina helps promote nucleation of the later formed TCO layer 202, such as an AZO film, compared to the glass substrate 114 itself. An AZO film has an oxygen rich surface and bonds especially well with alumina because of alumna's affinity to oxygen, which further promotes the growth of the AZO film. Indeed, the aluminum content in an AZO film may be quite small, and the nucleation promotion due to the aluminum content in the layer comprising alumina may also be quite small compared to the nucleation promotion due to the porosity and high oxygen content of alumina.

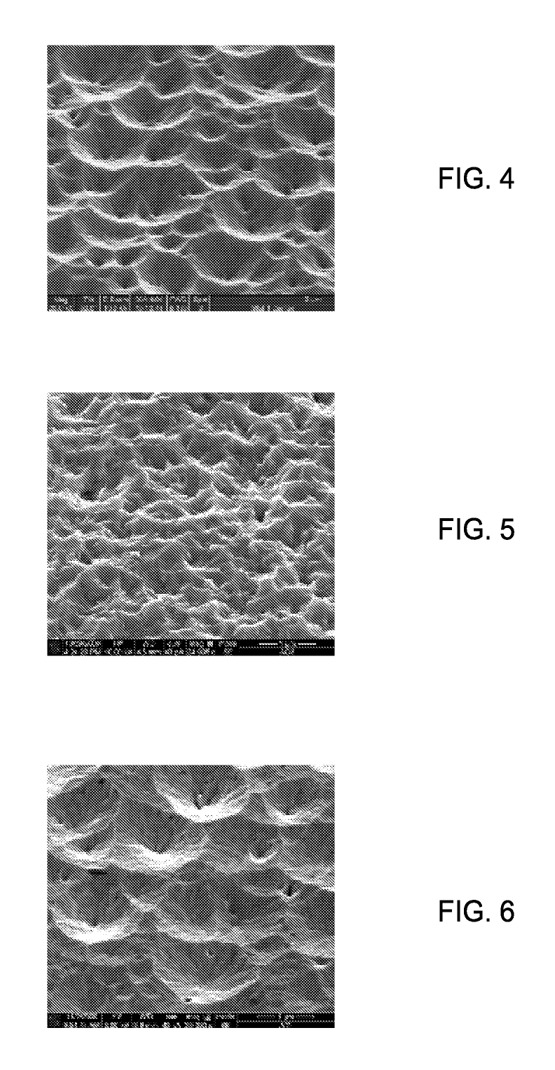

Another improvement in the solar cell device when using the layer comprising alumina 220 is that the coefficient of thermal expansion (CTE) of alumina is closer to glass than the TCO layer 202, which further aids in bonding and stress release of the deposited layers during later manufacturing. Moreover, deposition of an NPL layer comprising alumina also promotes (103) and (002) grain crystal structure of the transparent conductive layer, such as TCO layer 202. It is believed that the TCO layer 202 preferably forms a (002) and a (103) crystal orientation because of the layer comprising alumina 220, and thus the layer comprising alumina 220 promotes that particular crystal orientation in some films formed on the alumina Examples of this desired crystal grain structure and the resultant surface morphology are further described below with reference to FIGS. 4-6 illustrating comparative examples and an example formed using embodiments of the invention.

It has also been found that depositing with certain magnetron structures and types, target shapes, and wafer spacing configurations provides improved texture or grain orientation in subsequent TCO films deposited on the layer comprising alumina. For example, the flux of the target to surface may be best promoted using a ring magnetron structure. The ring structure forms a “race track” along the outer area of the target, which helps to form a fairly uniform film all over the glass substrate.

FIGS. 2B and 2C also depict other embodiments of the invention. In FIG. 2B a transparent barrier layer 221 is disposed between the layer comprising alumina 220 and the TCO layer 202. The barrier layer may be necessary to prevent later migration of contaminants from the glass through the layers. Soda lime glass has a high sodium content, which, if it diffuses through the layers to the photoelectric unit 214, will poison the PV solar cell 200, reducing its efficiency or even rendering it completely nonfunctional. Thus, a transparent barrier layer 221 may help block sodium from diffusing into the layers on the glass substrate. In one embodiment, the barrier layer may be a silicon layer including amorphous or polysilicon, SiON, SiN, SiC, SiOC, silicon oxide (SiO₂) layer, doped silicon layer, or any suitable silicon containing layer, or titanium dioxide. The transparent barrier layer 221 may be formed according to known techniques and methods in the art.

FIG. 2C depicts a barrier layer 223 comprising alumina. Forming an alumina barrier layer 223 may be done similarly to formation of the NPL layer comprising alumina 220 as previously described. After annealing the NPL layer comprising alumina 220 as described in the annealing process above, the substrate is placed back into the PVD chamber 100. Another aluminum layer is deposited on the NPL layer comprising alumina 220, thereby forming an alumina barrier layer 223. The aluminum layer is deposited until the thickness of alumina barrier layer 223 is from about 100 Å to about 500 Å thick. The amorphous nature of the alumina barrier layer 223 tends to prevent sodium in the glass substrate 114 from passing through the crystal boundaries of the alumina and diffusing into the photoelectric unit layers 214, making it a good barrier layer for use on soda lime glass. The barrier layer is then annealed according to the above annealing processes to help increase density of the alumina barrier layer 223. Following formation of any of barrier layers 221, 223, the substrate may be returned to the PVD chamber for TCO film formation.

Turning to FIG. 3, formation of the transparent conductive layer will now be described. TCO layer 202, a transparent conductive layer, may be deposited on the substrate 114. The TCO layer 202 may be, for example, a zinc oxide-containing transparent conductive layer such as ZnO:Al or AZO. FIG. 3 depicts a flow diagram of one embodiment of a sputtering deposition process 300 for depositing an NPL layer comprising alumina 220 and a transparent conductive layer, such as TCO layer 202, on the substrate 114. The process 300 may be stored in the memory 158 as instructions that when executed by the controller 148, cause the process 300 to be performed in the process chamber 100. It is contemplated that the method 300 may be performed in other systems.

A substrate is disposed in a PVD chamber at process 302. In one embodiment, the layer comprising alumina 220 may be formed on the substrate 114. The substrate may be subjected to a preclean process to remove any unwanted material from the substrate surface. The preclean process may be performed by any convenient method, such as by sputtering with argon or helium plasma, or by plasma cleaning such as with a reactive plasma or etchant plasma.

At process 304, a process gas mixture is supplied into the sputter process chamber. The process gas mixture supplied in the sputter process chamber assists in bombarding the source material from the target 120 to deposit aluminum material which will then form the desired layer comprising alumina 220 on the substrate surface when it reacts with oxygen. In one embodiment, the gas mixture may include a non-reactive gas. Examples of non-reactive gas include, but are not limited to, inert gas, such as Ar, He, Xe, and Kr, or other suitable gases.

In one embodiment, the argon (Ar) gas supplied into the sputter process chamber assists in bombarding the target to sputter materials from the target surface. The sputtered materials from the target, such as an aluminum target, deposit an aluminum layer on the substrate. The aluminum may react with oxygen and/or water on the glass substrate surface to form alumina. The gas mixture and/or other process parameters may be varied during the sputtering deposition process, thereby creating the layer comprising alumina with desired film properties for different film quality requirements. The Ar gas may be supplied into the processing chamber 100 at a flow rate up to about 100 standard cubic centimeters per minute (sccm), such as between 2 sccm and 100 sccm. In one embodiment the Ar gas flow rate is about 30 sccm. The flow rates may also be on a per liter of volume chamber basis. For example, the Ar gas flow rate may be from about 0.05 sccm per liter chamber to about 3.50 sccm per liter chamber, for example from about 0.95 sccm per liter chamber to 1.05 sccm per liter chamber.

At process 306, DC power is supplied to the target 120 to sputter the source material from the target 120. A high voltage power is supplied to the aluminum (Al) target 120. The power applied between the target 120 and the substrate support 138 maintains a plasma formed from the gas mixture in the process chamber 100. The ions created by the gas mixture in the plasma bombard and sputter off material from the target 120. In one embodiment, a DC power of between about 100 Watts and about 500 Watts may be supplied to the target. In another embodiment, the DC power may be supplied at a DC power density between about 5 W/cm² substrate surface and about 20 W/cm² substrate surface, such as about 15 W/cm² substrate surface. Lower power may provide a better ability to control the thickness of the aluminum layer.

At process 308, as the sputtered off material from the target 120 deposits on the substrate 114, a layer comprising alumina 220 with desired composition is formed on the substrate surface. Subsequent formation of the layer comprising alumina 220 was previously described, including further annealing processes. Further aluminum deposition processes may also occur such as when forming an alumina barrier layer 223 as previously described.

To further improve the surface morphology of the TCO layer 202, two (or more) parts of the TCO layer having a seed layer 222, such as a zinc oxide-containing transparent conductive seed layer and a bulk layer 224, such as a zinc oxide-containing transparent conductive bulk layer, can be deposited one after another to form the TCO layer 202. According to embodiments of the invention, at 310, a transparent conductive seed layer 222 is formed on the layer comprising alumina 220. Formation of the transparent conductive seed layer 222 may also be done in the same type of PVD chamber as formation layer comprising alumina 220 or the same cluster tool. The target 120, however, is different than for the formation of the layer comprising alumina 220, as previously described previously in connection with FIG. 1, e.g. the target is Zn rather than Al. The transparent conductive seed layer 222 may be formed between the layer comprising alumina 220 and the transparent conductive bulk layer 224. The transparent conductive seed layer 222 may be a TCO seed layer, such as an AZO seed layer.

Formation of the seed layer 222 and bulk layer 222 will now be discussed, beginning with seed layer 222. A process gas mixture, for example argon, is supplied into the sputter process chamber 100 to form the transparent conductive seed layer 222. The process gas mixture supplied in the sputter process chamber 100 assists in bombarding the source material from the target 120 and the sputtered material to deposits on the substrate to form the desired TCO seed layer on the substrate surface. In one embodiment, the gas mixture may include a reactive gas, a non-reactive gas, and combinations thereof such as those gases previously described.

The TCO layer 202 may require film properties, such as relatively high textured surface, high transparency, and high conductivity. Formation of a nucleation promotion layer, i.e. the layer comprising alumina 220, helps to promote those desired texture properties. Controlling the power and pressure of the sputtering process helps form the desired seed and bulk layers to improve the overall properties of the TCO layer 202.

In one embodiment of forming the TCO seed layer 222, a DC power of between about 450 Watts and about 550 Watts may be supplied to the target, such as about 500 watts. Alternatively, the DC power may be supplied at a DC power density between about 15 W/cm² substrate surface and about 119 W/cm² substrate surface, such as about 15 W/cm² substrate surface. The transparent conductive seed layer 222 may be formed at a substrate support temperature between about 370° C. to 430° C., a pressure between about 2.5 mTorr to about 2.8 mTorr, and at a deposition rate of between about 5 nanometers (nm) per minute to about 10 nanometers (nm) per minute. The seed layer may be about 200 Å thick. In one embodiment, the glass substrate temperature is between about 240° C. to about 370° C., such as about 240° C. to about 330° C. The sputtering gas may be Ar or a mixture of Ar and O₂, where O₂ is less than 10% of the sputtering gas mixture.

In another embodiment, the transparent conductive seed layer 222 is annealed prior to forming the transparent conductive bulk layer 224. Annealing or heat treating the seed layer may be performed in an argon atmosphere at about 275° C. to about 450° C., for example from about 275° C. to about 280° C. The seed layer annealing may last for about 1 minute to 30 minutes, such as about 5 minutes, and the chamber may be pressurized to at least 4 Torr, for example 7.5 Torr. The temperature of the seed layer anneal should be about 40° C. to about 50° C. higher than the seed layer deposition temperature. However, the annealing process should not pass the glass softening temperature. Heat treating the seed layer 222, which may be amorphous, may help provide re-crystallization of the seed layer 222 in the preferred orientation previously discussed.

After depositing a transparent conductive seed layer 222 to a thickness of less than about 250 Å, such as between about 200 Å and 250 Å, sputtering conditions may be adjusted to deposit a transparent conductive bulk layer 224 at process 312. The conditions may be adjusted gradually by ramping up the power to the level desired over time. Ramping up the power may produce an interface layer with a graded composition that smoothly transitions from a first composition resembling the composition of the transparent conductive seed layer 222 to a second composition resembling the composition of the transparent conductive bulk layer 224. The seed layer 222 may contain between about 5 atomic % to about 10 atomic % of Al while the bulk layer 227 may contain between about 1 atomic % to about 5 atomic % Al, such as 2 atomic %. The interface layer formed by the power ramping process provides a graded composition between the seed and bulk layers 222, 224, and overlaps their respective ranges. In one embodiment, the interface layer may include between 4 atomic % to 7 atomic % Al.

In one embodiment of forming the bulk layer 224, a DC power of between about 4,500 Watts and about 5,500 Watts may be supplied to the target, such as 5,000 Watts. The transparent conductive seed layer may be formed at a substrate support temperature between about 370° C. to about 430° C., a pressure between about 2.5 mTorr to about 2.8 mTorr, and a deposition rate of between about 65 nm per minute to about 75 nm per minute. The spacing between the glass substrate and the target may be between about 170 millimeters (mm) and about 200 mm, such as about 190 mm. In one embodiment, the glass substrate temperature is between about 240° C. to about 370° C. The DC power may be pulsed at 50 KHz with a duty cycle of 10-40% off time. The bulk layer may be from about 8,000 Å to 10,000 Å thick.

In another embodiment, after formation of the TCO layer 202, a wet etch process is performed on the TCO layer 202 to provide the final surface texture and roughness. In one embodiment, the TCO layer 202 is wet etched for 60 to 90 seconds each, using 1% HCl.

Formation of the TCO layer 202 in a two-step process of forming first a seed layer 222 followed by a bulk layer 224 deposition enlarged the temperature process window compared to a single TCO layer formation process. The temperature process window for formation of a single TCO layer is from 300° C. to 310° C., a tight 10° C. window, whereas the two-step process temperature window is between 370° C. to 430° C., a broader 60° C. window that provides much improved flexibility in processing conditions. Additionally, overall film uniformity is improved. It should be noted, however, that, although not shown in the figures, in some embodiments, the seed layer may be formed between the glass substrate 114 and the transparent conductive bulk layer 224 with no layer comprising alumina 220 present.

FIGS. 4-5 show comparative examples of TCO films on different glass substrates formed according to conventional methods. FIGS. 4-5 are micrographs of an etched AZO film formed using conventional methods. FIG. 6 shows an example of a TCO film formed on a lower grade glass according to embodiments of the present invention. FIG. 4 shows a wet etched AZO film formed on a borosilicate glass. Borosilicate glass is typically used to form solar cells because of its specific properties and lack of contaminants. For example, borosilicate glass also includes 17%-26% alumina content, whereas soda lime glass has 1-3% alumina content and sodium, which can diffuse into and thus poison the solar cell. However, borosilicate glass substrates and similar higher grade glass substrates are more expensive as compared to lower grade glass substrates, such as soda lime glass or low iron float glass substrates. The etched AZO film in FIG. 4, which is formed on borosilicate glass, has a crystal grain orientation of (002) and (103) and the desired texture and surface roughness, which has been shown to provide improved light scattering properties of the AZO film. The AZO film in FIG. 4 was formed using conventional deposition procedures (a single AZO film deposited in a PVD chamber) followed by conventional wet etching methods of the AZO film to provide the surface texture and roughness.

FIG. 5 shows a micrograph of a wet etched AZO film formed on a soda lime glass substrate using conventional methods. As is shown in FIG. 5, the grain structure is not similar to the desired (002) and (103) type of crystal orientation and thus lacks the surface roughness and texture desired for producing haze, even after conventional etching methods. Soda lime glass substrates and other similar commercially available less expensive substrates create the wrong crystal orientation of TCO films using conventional methods of forming TCO films. Without those two types of crystal orientation, the TCO film will have many reflections which decrease the efficiency of the solar cell.

In contrast, FIG. 6 shows a micrograph of an etched AZO film on soda lime glass formed according to embodiments of the invention. A layer comprising alumina, a nucleation promotion layer, is first formed on the soda lime glass followed by AZO film deposition in a PVD chamber. Both micrographs in FIGS. 4 and 6 have Julich-like structures with (002) and (103) crystal orientation even though the glass substrates are different. Using embodiments of the invention, the AZO layer will form a crystalline structure on lower grade glass, such as soda lime glass, similar to more expensive borosilicate glass substrates. Additionally, the AZO layer crystalline structure is formed not just in localized areas but across large surface areas.

Embodiments of the invention provide the desired texture properties by controlling actual film surface morphology during film deposition itself as compared to conventional wet etch methods. In other words, embodiments of the invention promote a desired texture by using material properties to achieve a particular surface morphology compared to etchant based methods which merely texturize the already formed crystalline structure to achieve desired surface roughness.

Forming a thin nucleation promotion layer comprising alumina on the glass substrate leads to the preferred crystal orientation (002) and (103) of the grains and desired film properties of the subsequently deposited transparent conductive layer, such as an AZO film. This results in increased solar cell efficiency due to better light trapping of near infrared (NIR) wavelength light. Additionally, the disclosed embodiments may be applicable to any type of glass substrate including commercially available low iron float glass and soda lime glass. Thus, embodiments of the invention not only enable the use of cheaper and more readily obtainable types of glass substrates for photovoltaic device manufacturing, but they also improve the haze (i.e., light scattering) of solar cell devices making them more efficient.

While the foregoing is directed to embodiments of the invention, other and further embodiments of the invention may be devised without departing from the basic scope thereof.

What is claimed is:

1. A method of forming a solar cell, comprising:
forming a layer comprising alumina on a substrate; and
forming a transparent conductive layer on the layer comprising alumina.

2. The method of claim 1, wherein the oxygen in the alumina is sourced, at least in part, from the substrate.

3. The method of claim 1, wherein forming the layer comprising alumina further comprises:
depositing a layer comprising aluminum on a substrate within a processing chamber; and
annealing the layer comprising aluminum to form the layer comprising alumina.

4. The method of claim 1, wherein annealing the layer comprising aluminum is performed at about 450° C. in an argon atmosphere for about 5 minutes.

5. The method of claim 1, wherein the layer comprising alumina further comprises a matrix of at least one of the following: aluminum and alumina, nano particles in aluminum, aluminum nano particles in alumina.

6. The method of claim 1, wherein forming the transparent conductive layer further comprises:
forming a zinc oxide-containing transparent conductive seed layer on the layer comprising alumina;
performing a break in the process; and
forming a zinc oxide-containing transparent conductive bulk layer on the zinc oxide-containing transparent conductive seed layer.

7. The method of claim 1, further comprising:
forming a barrier layer on the layer comprising alumina prior to forming the transparent conductive layer.

8. The method of claim 7, wherein forming the barrier layer further comprises:
depositing an aluminum layer on the layer comprising alumina within a processing chamber; and
annealing the aluminum layer to form the barrier layer comprising alumina.

9. The method of claim 1, wherein the substrate is selected from the group consisting of: glass, alumino-borosilicate glass, borosilicate glass, low iron glass, and soda lime glass.

10. The method of claim 1, wherein the layer comprising alumina is amorphous.

11. The method of claim 1, wherein the layer comprising alumina comprises a porous network.

12. The method of claim 7, wherein the barrier layer is amorphous.

13. A method of forming a solar cell, comprising:
forming a nucleation promotion layer comprising alumina on a substrate;
forming a barrier layer on the nucleation promotion layer;
forming a zinc oxide-containing transparent conductive seed layer on the barrier layer; and
forming a zinc oxide-containing transparent conductive bulk layer on the zinc oxide-containing transparent conductive seed layer.

14. The method of claim 13, wherein the layer comprising alumina further comprises a matrix of at least one of the following: aluminum and alumina, nano particles in aluminum, aluminum nano particles in alumina.

15. A photovoltaic device, comprising:
a substrate;
a layer comprising alumina adjacent to the substrate;
a zinc oxide-containing transparent conductive seed layer adjacent the layer comprising alumina;
a zinc oxide-containing transparent conductive bulk layer adjacent to the zinc oxide-containing transparent conductive seed layer.
